(19) United States
(12) Patent Application Publication
(10) Pub. No.: US 2008/0053523 A1
(43) Pub. Date: Mar. 6, 2008

(54) SOLAR CELL INTERCONNECT

(76) Inventors: Acie BROWN, Nashville, NC (US); Loren D. OTA, Rocky Mount, NC (US); Harold R. MCCONNELL, Nashville, NC (US); Donald I. EDWARDS, Nashville, NC (US)

Correspondence Address: Ishman Law Firm P.C., P.O BOX 1245, Cary, NC, 27512-1245, US

(21) Appl. No.: 11/846,377

(22) Filed: Aug. 28, 2007

Related U.S. Application Data
(60) Provisional application No. 60/841,069, filed on Aug. 30, 2006.

(51) Int. Cl. H01L 31/02; B23K 13/01

(52) U.S. Cl. 136/256; 219/615

(57) ABSTRACT

A solar cell interconnect includes an elongated composite member having a nickel/iron based core of rectangular cross section peripherally metallurgically connected with a copper based covering, the core having elongated longitudinal grooves in opposed top and bottom into which the covering is mechanically swaged.

### RELATED APPLICATION

This application claims the benefit of U.S. Provisional Application No. 60/841,069 filed on Aug. 30, 2006 and entitled “Solar Cell Interconnect”.

### FIELD OF THE INVENTION

The present invention relates to solar cells and, in particular, to electrical connections between solar cells.

### BACKGROUND OF THE INVENTION

A problem encountered in the construction of solar panels is the thermal mismatch between the cell interconnect conductors and the cell substrate. Particularly for silicon cell substrates with copper interconnects, this thermal expansion mismatch can result in breakage of the silicon cell or the conductor during assembly or thermal cycling.

Certain attempts have been made to alleviate the expansion problem by using a conductive composite or alloy having a linear expansion coefficient closer to the substrate to reduce the assembly and operational strains leading to cell failure. While many conductive materials satisfy this condition, such as iron alloys, tungsten, molybdenum and the like, the requisite electrical conductivity is inferior to that of the normal copper and copper alloys used for the interconnect. Accordingly, there has been an effort in solar cells and other silicone substrate devices to provide alloys and composite structures that reduce the coefficient of thermal expansion level while retaining desired electrical conductivity.

U.S. Pat. No. 5,310,520 to Jha et al. all discloses composite materials of powdered copper and iron alloy, INVAR, that are blended, heat degassed, heat extruded, and processed to connected to product size. The process is time consuming and expensive. United States Patent Application Publication No. 2004/0244828 to Nishikawa et al. discloses a composite material wherein a rectangular cross section core of INVAR is exteriorally clad by a copper coating. Although claiming to satisfy the above mentioned performance requirements, no method of manufacture or performance data is disclosed. Further, experience has shown that mere clad composites of the differing expansion coefficients are subject to lateral and longitudinal delamination over time and under severe thermal operating conditions. Should such delamination occur in the composite interconnect, the thermal expansion coefficient of the copper would be dominant leading to premature substrate failure.

It would accordingly be desirable to provide a solar cell interconnect having a favorable manufacturing price, acceptable performance, and a balance of properties enabling long term stable and efficient operation.

### SUMMARY OF THE INVENTION

The present invention provides a solar cell interconnect, a method for making same, that overcomes the problems associated with thermal mismatch that can be efficiently manufactured, provides acceptable thermal and electrical performance, with long term dependability. The solar cell interconnect includes an elongated composite strip having a nickel-iron alloy core of rectangular cross section peripherally metallurgically connected with a copper covering, the core having elongated longitudinal grooves in opposed lateral surfaces into which the covering is mechanically swaged thereby increasing the bonded surface area and providing a mechanical interlock resisting delamination. The connector may be made in a continuous rolling process. Preferred core materials are Alloy 42 and Alloy 36. These composites are designed to be closer to the thermal expansion coefficients of the base substrate than copper and solder alone. The ratio of copper to alloy determines the thermal expansion and the electrical conductivity. This ratio can be tailored to meet customer specifications. The alloy core, clad with copper on all sides, is rolled flat to the required dimensions and dipped on a continuous basis in conventional solders without process alteration to meet the market's requirements.

### BRIEF DESCRIPTION OF THE DRAWINGS

The above and other features of the invention will become apparent upon reading the following description taken in conjunction with the accompanying drawings in which:

FIG. 1 is an end view of a solar cell interconnect connected to solar cells;

FIG. 2 is a transverse cross sectional view of the interconnect;

FIG. 3 is a transverse cross section view of the interconnect with a solder coating;

FIG. 4 is a fragmentary photographic cross section of the interconnect;

FIG. 5 is a photographic cross section of an interconnect removed from a solder connection at a substrate;

FIG. 6 is a schematic cross sectional view of the groove in the core of the interconnect; and

FIG. 7 is a schematic elevational view of the rolling apparatus for forming the interconnect.

### DESCRIPTION OF THE PREFERRED EMBODIMENTS

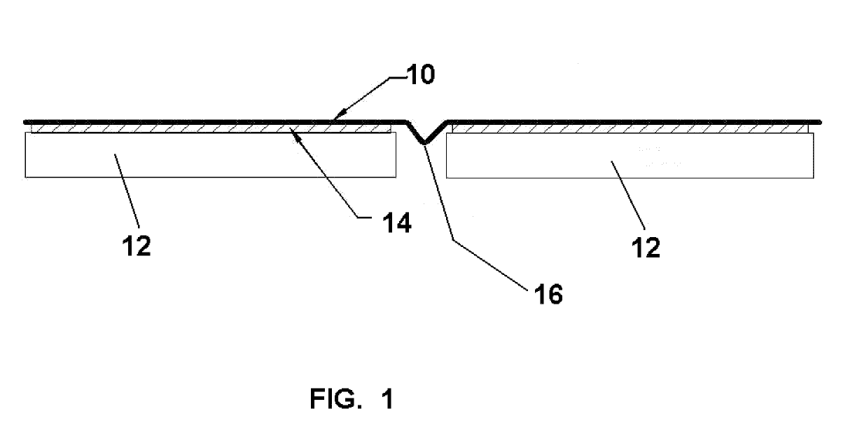

Referring to FIG. 1, there is shown a solar cell interconnect 10 electrically connected in series to a plurality of solar cells 12 at a solder connection at the cell substrate 14. The interconnect 10 is elongated in strip form and includes an expansion joint 16 between adjacent cells 12.

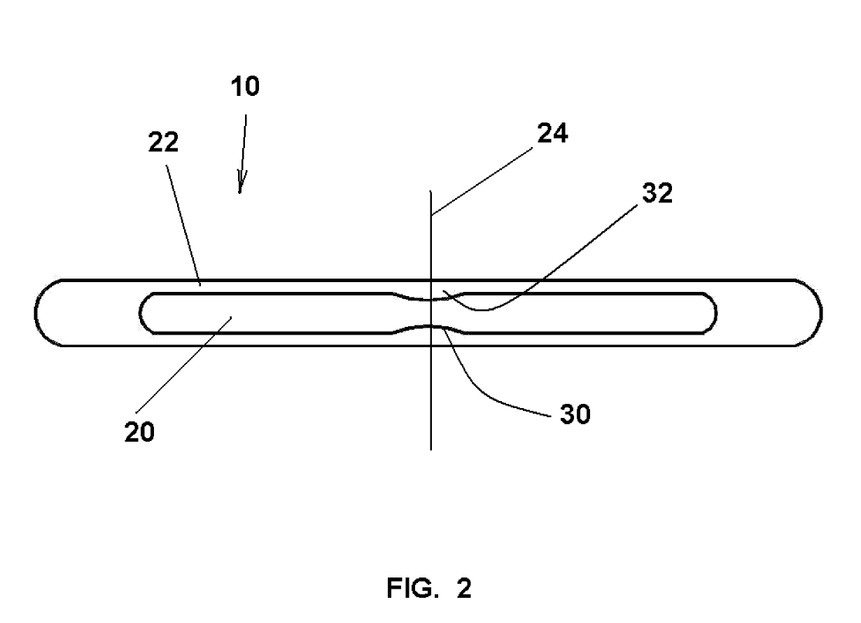

Referring to FIG. 2, the interconnect 10 comprises a core 20 of a first material metallurgically clad with a covering 22 of a second material. The covering is a copper based material, preferably copper or a copper alloy. The core is a nickel/iron based material, preferably a nickel alloy with iron with nickel in the range of about 30-60% by weight. Suitable nickel alloys include Alloy 42, Alloy 36 (INVAR), and Alloy 52.

The core 20 is generally rectangular in cross section. The covering 22 is generally symmetrical with the core 20 about a vertical longitudinal plane 24, with the lateral sides of greater width than the top and bottom thicknesses.

The core 20 includes opposed longitudinal grooves 30 in the top and bottom surfaces. The covering 22 includes opposed longitudinal tabs 32 mechanically swaged into the grooves 30. The grooves 30 and tabs 32 are established during the roll forming process described below. In assembly, the core 20 is metallurgically bonded to the covering 22. As described below, the tabs 32 and grooves 30 interact to provide increased shear surfaces resisting longitudinal and lateral delamination between the core and covering. The construction also provides increased copper content, and thus improved electrical conductivity, than strip laminates or simply clad cores.

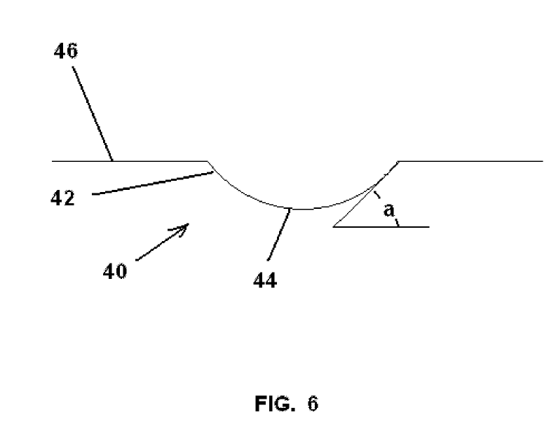

Referring to FIG. 6, the resultant grooves 40 are generally rounded V-shapes having converging slightly curvilinear longitudinal side walls 42 with a rounded base 44. The angle “a” of the side walls in the vicinity of the exit surface 46 is preferably between 10° and 60° with respect to the entering top or bottom surface of the core. At shallower angles outside the range, minimal resistance is provided. For steeper angles, the penetration into the core becomes excessive, in that it is preferred to keep the depth of the groove at about 10% to 30% of the core thickness. At higher depths, excess rolling forces are required. At lesser depths, delamination resistance approaches planar configurations. Within the range, additional conductive covering material can be incorporated for a selected aspect ratio thereby improving conductivity. The compressive mechanical interlock limits delamination forces to the outer lateral margins.

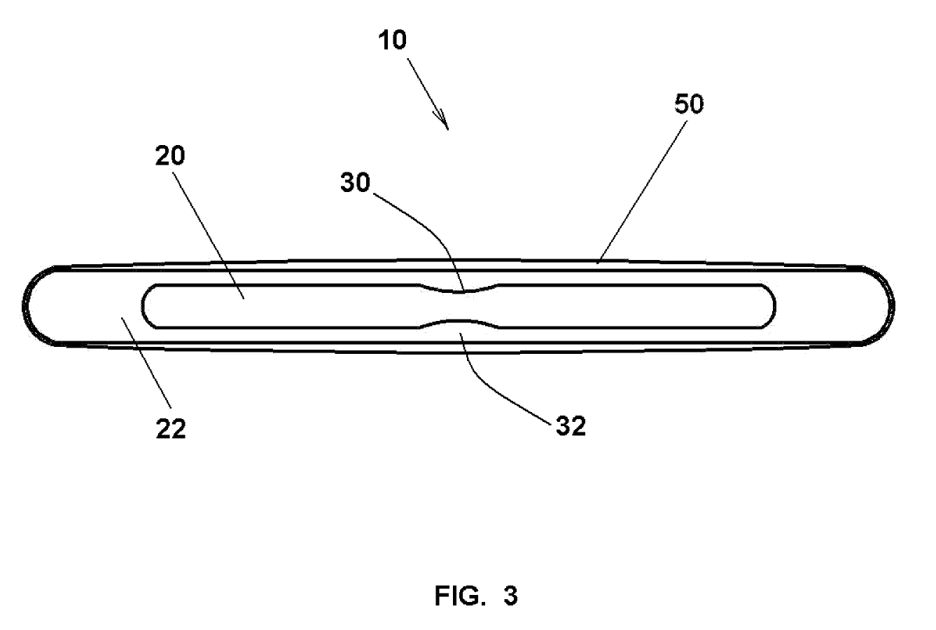

Referring to FIG. 3, preparatory to assembly with the solar cells, a peripheral solder coating 50 may be applied to the exterior surface of the connector 10 by suitable conventional processes.

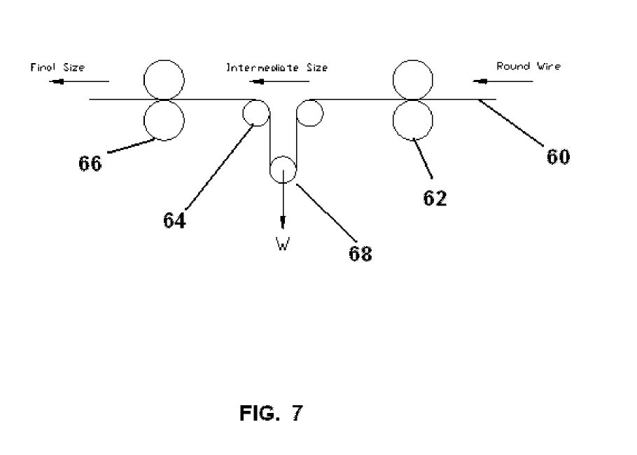

Referring to FIG. 7, the interconnect is made in a two stage rolling operation starting with a circular core of the nickel/iron alloy. The round core is mechanically surface cleaned, and preheated and annealed in a reducing atmosphere to provide additional surface cleaning. The copper covering is made starting with a strip of material, which is also preheated and annealed in a hydrogen atmosphere to provide surface cleaning. The two materials are bonded together by rolling in grooved dies in a continuous process using high pressure and high temperature. This cladding process creates a composite wire 60 having a metallurgical bond between the core alloy and the copper covering. Once the material is drawn to the proper size, the wire 60 is fed between cylindrical entry rolls 62 through intermediate speed synchronizing roller assembly 64 to cylindrical exit rolls 66. The wire span intermediate the rolls 62, 66 is subjected to a weight load 68. The resultant composite has comparable covering thicknesses on the top and bottom surfaces and increased lateral thicknesses at the sides. The depth and wall angle of the groove/tab interlock are primarily determined by the thickness reduction at the entry rolls 62, the feed speed of the wire 60 and the weight load 68. Greater thickness reduction and/or weight and feed speed create greater interlock depth and width. Reduced levels on these conditions produce shallower interlocks. The metallurgical bond between the materials insures that no separation occurs and that the material maintains the desired aspect ratio. Further, the resultant tab and groove interface provides increased strength resisting lateral and longitudinal delamination. The formed interconnect is then hot dipped in any required solder alloys and spooled for shipment.

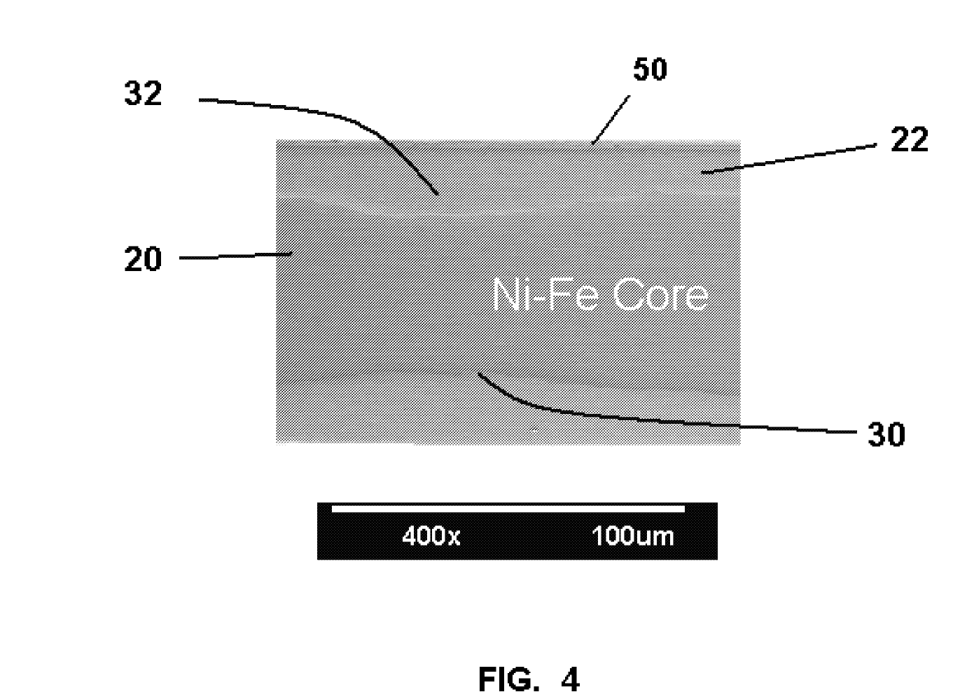

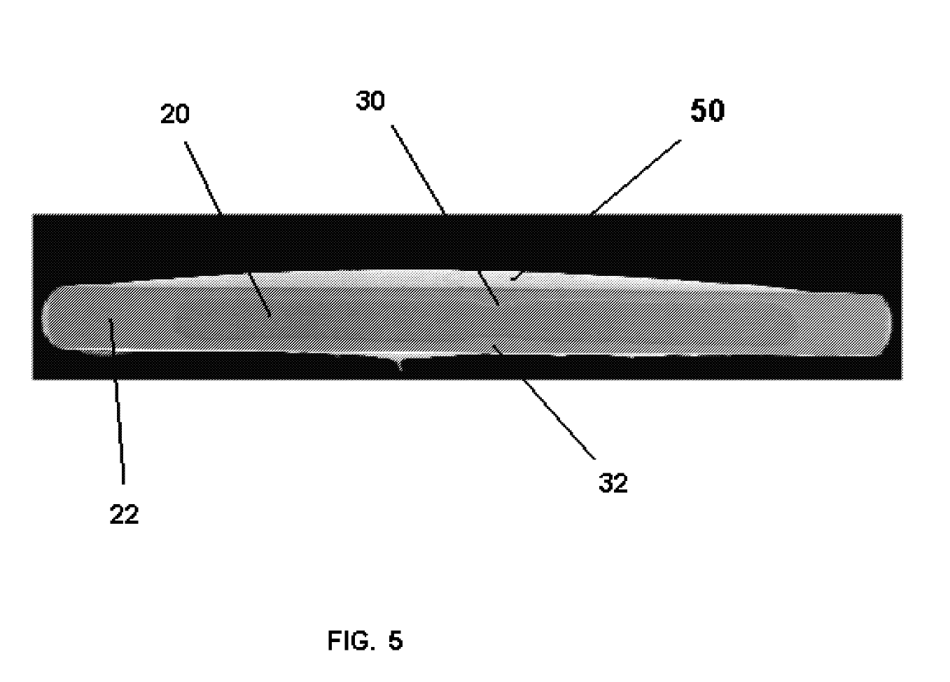

FIGS. 4 and 5 are photographs of an interconnect made in accordance with the foregoing method and having a ratio of 55% copper to nickel alloy. The nickel alloy is Alloy 42. The core has a width of 0.0456 inch and a thickness of 0.0026 inch. The covering has a thickness of 0.004 inch and an overall width of 0.060 inch. The core grooves have a depth of 0.0005 inch. Testing has determined the average resistance of the material without the solder coating is 5.53 milliohms per inch. The average resistance of the solder coated material is 5.23 milliohms per inch. The 0.2% yield of the material without the solder coating averages 31,300 psi per ten samples. The 0.2% yield of the solder coated material averages 37,776 psi per ten samples. The elongation of the material without the solder coating is 26.7%. The elongation of the solder coated material is 21.6%. Such a connector provides an acceptable coefficient of thermal expansion for assembly and thermal cycling.

The connector may also be adapted to interface with stainless steel flexible solar panel substrates. A highly acceptable connector for such applications comprises a core of Alloy 36 (INVAR) at 31% by weight and a copper covering at 69% by weight providing a thermal expansion coefficient of 8.4 um/m° C. A core of Alloy 42 at 31% by weight and a copper covers at 69% provides a thermal expansion coefficient of 10.4 um/m° C.

While the invention has been described with primary reference to solar applications, it will be apparent that the thermal compatibility herein provided may be used in other connecting applications wherein it is desired to reduce manufacturing and operating problems associated with disparate thermal characteristics.

Having thus described a presently preferred embodiment of the present invention, it will now be appreciated that the objects of the invention have been fully achieved, and it will be understood by those skilled in the art that many changes in construction and widely differing embodiments and applications of the invention will suggest themselves without departing from the sprit and scope of the present invention. The disclosures and description herein are intended to be illustrative and are not in any sense limiting of the invention, which is defined solely in accordance with the following claims.

What is claimed:

1. A solar cell interconnect comprising: an elongated composite member having a core of nickel/iron alloy, said core having a rectangular cross section peripherally and metallurgically connected with a copper based covering, the core having elongated longitudinal grooves in opposed top and bottom surfaces into which said covering is mechanically swaged.

2. The interconnect as recited in claim 1 wherein said composite member includes an exterior solder coating.

3. The interconnect as recited in claim 2 wherein said alloy is in the range of 30% to 60% by weight.

4. An electrical connector for attachment to a substrate comprising: a core of a nickel/iron based alloy, said core having an elongated length and a width greater than thickness; a covering of an electrically conductive metallic material surrounding and mechanically formed against said core establish a composite wherein said covering has a continuous longitudinal projecting surface penetrating into said core at opposed surfaces, said composite having a coefficient of thermal expansion closer said substrate than copper.

5. The connector as recited in claim 4 wherein said substrate is silicon and said alloy contains nickel in the range of 30% to 60% by weight.

6. The connector as recited in claim 5 wherein said alloy is Alloy 42.

7. The connector as recited in claim 4 wherein said substrate is stainless steel and said alloy is Alloy 36.

8. The connector as recited in claim 4 wherein said longitudinal projecting surface is laterally centered on opposed top and bottom surfaces of said core.

9. The connector as recited in claim 8 wherein said projecting surfaces includes opposed side walls having an angle with said top and bottom surfaces of about 10° to 60°.

10. The connector as recited in claim 9 wherein said projecting surfaces each extend into said opposed surfaces about 10% to 30% of said thickness of said core.

11. The connector as recited in claim 10 wherein the thickness of said covering at side surfaces of said core is substantially greater than the thickness of said covering at said top and bottom surfaces.

12. A method of making an interconnect for a solar cell substrate comprising the steps of:
a. providing an elongated circular core of a nickel/iron alloy;
b. peripherally cladding said core with a layer of copper;
c. roll forming said core clad with copper under conditions providing a composite of rectangular cross section and forming inner longitudinally projecting surfaces of said layer mechanically swaged into opposed surfaces of said core.

13. The method as recited in claim 12 wherein said surfaces project 10% to 30% of the thickness of said core following said forming.

14. The method as recited in claim 13 wherein said nickel/iron alloy is selected from the group consisting of Alloy 36 and Alloy 42.

15. The method as recited in claim 14 wherein said composite has a coefficient of thermal expansion closer to the solar cell substrate than copper.

16. The method as recited in claim 15 wherein said composite comprises 30% to 60% nickel/iron alloy by weight.
